(19) United States
(12) Patent Application Publication
(10) Pub. No.: US 2019/0140162 A1
(43) Pub. Date: May 9, 2019

(54) PIEZOELECTRIC CERAMIC, METHOD FOR THE PRODUCTION THEREOF AND ELECTROCERAMIC COMPONENT COMPRISING THE PIEZOCERAMIC

(71) Applicant: EPCOS AG, Munich (DE)

(72) Inventors: Denis OROSEL, DEUTSCHLANDSBERG (AT); Markus PUFF, GRAZ (AT); Bernhard DOELLGAST, DEUTSCHLANDSBERG (AT); Michael SCHOSSMANN, DEUTSCHLANDSBERG (AT)

(21) Appl. No.: 16/095,324

(22) PCT Filed: Apr. 4, 2017
(86) PCT No.: PCT/EP2017/057973

§ 371 Date: Oct. 19, 2018

(30) Foreign Application Priority Data
Apr. 21, 2016 (DE) 10 2016 107 405.5

(51) Int. Cl. H01L 41/187; C04B 35/493; C04B 35/626; C04B 35/64; H01L 41/047; H01L 41/083; H01L 41/273

(52) U.S. Cl. CPC H01L 41/1876; C04B 2235/96; C04B 35/6261; C04B 35/64; H01L 41/0471; H01L 41/0477; H01L 41/083; H01L 41/273; C04B 2235/3249; C04B 2235/3262; C04B 2235/3281; C04B 2235/407; C04B 2235/408; C04B 2235/658; C04B 35/493

(57) ABSTRACT

A hard lead zirconate titanate (PZT) ceramic of the general structure ABO3 is specified, wherein the PZT ceramic has doping with Mn on the B sites and doping with Cu on the A sites and/or on the B sites. A process for producing a ceramic material and an electroceramic component are moreover specified.

The present invention relates to a hard lead zirconate titanate (PZT) ceramic as is used, for example, in piezoelectric components, in particular transducers. The invention further relates to a process for producing the hard PZT ceramic and also to a ceramic material which is obtainable by means of the process. Furthermore, the invention relates to an electroceramic component which contains the ceramic or the ceramic material.

Ferroelectric hard PZT materials can withstand high electrical and mechanical stresses. Resonance applications in particular, for example in the form of a piezoelectric transducer, profit from the properties of hard piezoelectric materials. A piezoelectric transducer having internal copper electrodes and a hard piezoceramic is known from WO 2004/032255 A2. However, such conventional material systems can lead to the piezoelectric component distorting during the sintering process. It is therefore an object of the present invention to provide a ceramic formulation which allows more dimensionally accurate production of an electroceramic component, for example a piezoelectric transducer.

This object is achieved according to the invention by the subject matter of the independent claims. Advantageous embodiments are subject matter of the dependent claims.

The inventive hard lead zirconate titanate (PZT) ceramic of the general structure ABO3 is characterized in that it has doping with Mn on the B sites and additionally doping with Cu on the A sites and/or on the B sites.

A hard PZT ceramic is obtained by doping of the basic composition with a doping element having a low valence (acceptor) compared to the corresponding lattice atoms on the A and B sites. Hard PZT ceramics can be characterized by low mechanical losses (Qm=1000 to 2000) and dielectric losses (tan δ=0.3 to 0.4%).

The present invention is based on the recognition that in the cosintering of multilayer piezoelectric ceramic components having internal copper electrodes, copper generally diffuses out from the electrodes into the ceramic. This copper becomes a constituent of the ceramic composition and influences the properties thereof, for example density, grain size and microstructure. Owing to the diffusion rate of copper, this influence is more pronounced in the region close to the copper electrodes than in ceramic regions which are further away from the electrodes. This can lead to problems when regions of the ceramic, for example isozones or high-voltage parts, are so far away from copper electrodes that diffusion of copper into these regions occurs only incompletely or not at all. Owing to the different copper contents in the regions close to the electrodes and remote from the electrodes, differences in the shrinkage of the ceramic then occur during the sintering operation. This leads to mechanical distortion of the components. At the same time, the different copper content impairs the uniform deflection of the ceramic during operation.

The inventive ceramic formulation is indicated, on the other hand, such that the significant lattice sites are occupied by copper as early as in the green ceramic. In this way, the exchange of copper between the electrodes and the ceramic during sintering has essentially no effect on the shrinkage and/or the deflection during working operation. As a result, the inventors have achieved improved maintenance of the geometry and improved deflection behavior of piezoelectric components having internal copper electrodes. At the same time, the advantageous materials properties of a hard PZT ceramic are maintained.

The PZT ceramic can have at least one further doping with Na, K, Ag, Nd, La, Ba, Sr, Ca or Bi on the A sites. Any combinations of these doping elements are also possible. The A sites preferably have doping with one or more low-valence cations, for example Na and/or K.

The B sites preferably have doping with Cu. Doping with Fe, Nb, Zn, Ge, Sn, Al, Ga or Sb or any combinations of these doping elements can also be present on the B sites. Apart from Cu, the B sites preferably also have doping with Nb.

The doping on the A sites and/or B sites of the ceramic preferably comprises up to 1.0 atom % of Cu, in particular from 0.05 to 0.1 atom % of Cu. The inventors have established that these amounts of copper in the PZT ceramic particular advantageously compensate for the effect of copper diffusion, so that the shrinkage and deflection behavior of the ceramic is essentially the same in regions with and without internal copper electrodes.

It is also possible for only the B sites and not the A sites of the ceramic to comprise Cu.

The doping on the B sites can comprise up to up to 5.0 atom % of Mn. Preference is given to from 2.0 to 3.0 atom % of Mn. In this way, particularly low dielectric losses combined with high electromechanical coupling efficiency are achieved.

In a preferred embodiment, the PZT ceramic has the general formula

(Pb1-(a·2/m)Mma·2/m)1-y(Zr1-x-(b·4/n)TixNnb.4/n)yO3.

Here, Mm represents one or more dopings M having the respective valence m, Nn represents one or more dopings N having the respective valence n. Furthermore: 0≤a≤0.1; 0<b≤0.2; 0.2≤x≤0.8 and 0.4≤y≤0.6.

Taking into account the valence of the constituents as indicated and correspondingly adapting the Pb content and Zr/Ti content of the composition ensures, according to the invention, that the electrical neutrality of the ceramic is maintained.

The ratio of (1-x-(b·4/n) to x is preferably in the range from 0.9 to 1.1. For y, preference is given to 0.4≤y≤0.6. For (a·2/n), preference is given to 0.0001≤(a·2/m)≤0.05. For (b·4/n), preference is given to 0.0001≤(b·4/n)≤0.1.

The present invention further provides a process for producing a ceramic material which comprises the above-described hard lead zirconate titanate (PZT) ceramic. The process comprises the steps:

A) Provision of starting materials Pb, Zr and Ti and doping elements Mn and Cu and optionally additional doping elements,
B) Mixing and milling of the starting materials and doping elements to produce a starting mixture,
C) Sintering of the starting mixture to the hard PZT ceramic in order to obtain the ceramic material.

It is possible here for at least one of the doping elements in the starting mixture to be provided in a superstoichiometric proportion in relation to the proportion of the doping element in the hard PZT ceramic. Adhering to this prerequisite, the inventors were able to establish surprising self-regulation of the electrical neutrality of the PZT ceramic during the production process.

In a preferred process variant, step C) is carried out in a sintering atmosphere in which at least one of the doping elements can change its valence. This makes it possible, according to the invention, for the desired electrical neutrality of the ceramic composition to be established as a function of the process and to depend less strongly on the production of the starting mixture.

In a particularly advantageous process variant, at least part of at least one of the doping elements is reduced to the metal, i.e. to the oxidation state zero, in step C). The part of the doping element which has been reduced to the metal can precipitate in the form of small metal particles in the ceramic material.

Since these metal precipitates are no longer available to the ceramic composition, a type of buffered system between the doping element incorporated in the ceramic and the doping element which has been reduced to the metal is established, as has surprisingly been found by the inventors, as a result of which the proportion of the doping element in the ceramic becomes self-regulating. This surprising effect is, for example, advantageous to the production process since an electrically neutral ceramic composition is less dependent on the weighed-out amount of the doping element in the starting mixture or is influenced to a lesser degree by the extent of copper diffusion from electrodes into the ceramic composition.

A ceramic material which is obtainable by this process accordingly comprises the hard PZT ceramic and metallic precipitates, for example in particle form, dispersed in the PZT ceramic. The metallic precipitates or particles can comprise at least one of the doping elements in elemental form, in particular elemental copper or elemental silver.

The invention accordingly provides a ceramic composition comprising a ceramic component and a metallic component, wherein the ceramic component comprises a hard lead zirconate titanate (PZT) ceramic as described above. The metallic component here comprises a doping element, which is also present in the hard lead zirconate titanate (PZT) ceramic, in a form which has been reduced to the metal. This form can be amorphous and/or substantially particulate.

In particular, the abovementioned process variant provides for the doping element provided in the superstoichiometric proportion to be able to change its valence or be reduced to the metal in the sintering atmosphere. For example, Cu or, if present, Ag can be present in a superstoichiometric proportion. A change in valence from Cu(II) or Cu(I) to Cu(0) can, for example, be brought about in a reducing sintering atmosphere. For a change in valence from Ag(I) to Ag(0), sintering can be carried out in an oxidizing atmosphere, for example air. The sintering operation in step C) is preferably carried out in terms of the oxygen partial pressure and the temperature on the equilibrium line between the oxidized state and the metallic state of the doping element. Suitable conditions are known to those skilled in the art or can readily be predicted (Ellingham, H. J. T. (1944), “Transactions and Communications”, J. Soc. Chem. Ind. (London), 63, 125).

The starting mixture is preferably sintered at below 1000° C. to the hard PZT ceramic in step C). Preferred sintering temperatures are in the range from 920° C. to 980° C. In this way, it is possible to produce hard PZT ceramics which have a high density and display low dielectric losses and high electromechanical coupling efficiencies.

According to a further aspect, the invention provides an electroceramic component, in particular a transducer, having a monolithic multilayer structure. The component comprises a stack of superposed ceramic layers and at least two electrode layers located inbetween, wherein the electrode layers contain elemental copper and the ceramic layers comprise a hard PZT ceramic or a ceramic material according to the preceding description. The components according to the invention display a high dimensional accuracy and uniform deflection behavior.

The electroceramic component can be configured so that a ceramic layer of the stack has subregions adjoining electrode layers and subregions which are further away and are at a distance of more than 1.5 mm, in particular more than 2 mm or more than 4 mm, away from the electrode layers adjoining the ceramic layer. Such subregions which are further away are generally outside the diffusion zone of the copper which leaves the electrode layers during the sintering operation. In the case of conventional ceramics, copper contents which are so different that different shrinkage behavior occurs in the subregions and therefore distortion of the geometric shape of the component occur are often established in the subregions adjoining the electrode layers and subregions which are further away. At the same time, the different copper contents in the subregions have an adverse effect on the deflection behavior of the component. In comparison, the ceramic of the invention has the advantage that the effects of copper diffusion are superimposed or compensated for and the distortion in the finished component can be minimized or even avoided completely. As a result, the quality class of the electroceramic component is increased.

It is possible, for example, that the subregions adjoining the electrode layers and the subregions which are further away have copper contents which differ by not more than 10 atom %.

The advantages of the PZT ceramic of the invention become particularly apparent in the case of piezoelectric components having a large size, which are particularly susceptible to distortion of the geometric shape due to shrinkage processes. It is possible, for example, for the ceramic layers of the component of the invention to have a main surface which has a length of at least 50 mm or at least 70 mm. In certain configurations, the length of the main surface can be up to 150 mm or up to 100 mm. The width of the main surface can be at least 4 mm or at least 6 mm. The width of the main surface is preferably up to 25 mm or up to 18 mm. Furthermore, it is possible for not more than 75%, in particular not more than 60% or not more than 50%, of the main surface of one or more ceramic layers to be covered with an electrode layer. Such structural variants can be provided with particular dimensional accuracy by means of the PZT ceramic of the invention.

The invention will be illustrated below with the aid of figures and working examples, but these are not to be interpreted as restricting the subject matter of the invention. Rather, the invention encompasses each novel feature and each combination of features, which includes, in particular, any combination of features in the claims, even when this feature or this combination is itself not explicitly indicated in the claims or working examples.

FIG. 1 schematically shows a plan view of a main surface of a ceramic layer KS having an internal copper electrode EL arranged on the ceramic layer. The subregions AT adjoining the electrode layer and subregions ET which are further away are characterized by different patterns.

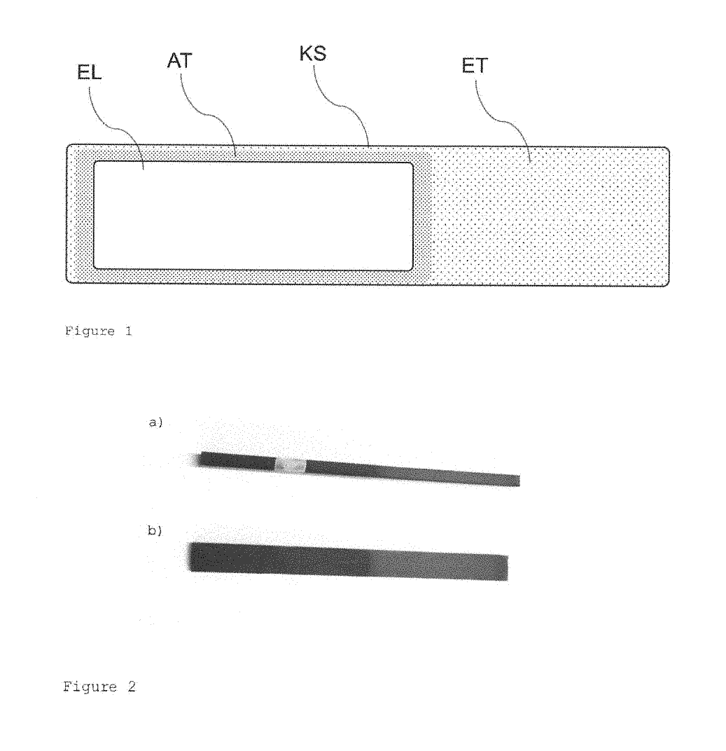

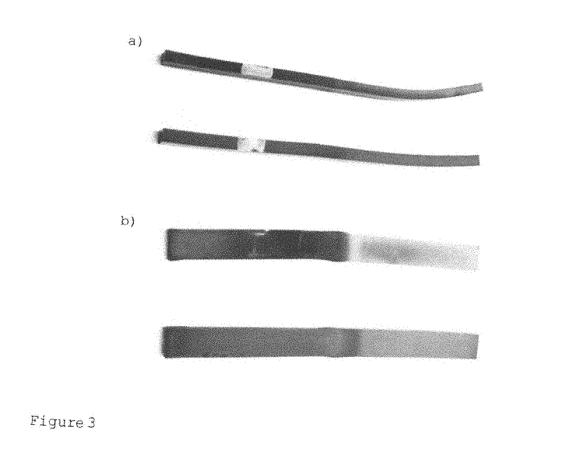

FIG. 2 shows photographs of a side face (a) and a main surface (b) of an electroceramic component having a monolithic multilayer structure with internal Cu electrodes and ceramic layers which have been made using a hard PZT ceramic according to the invention.

FIG. 3 shows photographs of side faces (a) and main surfaces (b) of electroceramic components having a monolithic multilayer structure with internal Cu electrodes and ceramic layers which have been made using a conventional hard PZT ceramic without Cu doping.

In a working example according to the invention, the PZT ceramic with dopings of 0.0075 atom % of Na on the A sites and 0.054 atom % of Nb, 0.027 atom % of Mn and 0.003 atom % of Cu on the B sites was tested. As comparative example, the corresponding PZT ceramic without Cu doping was used. The PZT ceramics were processed with internal copper electrodes in a monolithic multilayer structure to give electroceramic components. The ceramic layers had a main surface having a length of about 71 mm and a width of about 6 mm. The stack height of the components was about 2.8 mm. The electroceramic components made using the PZT ceramic of the invention displayed particularly advantageous properties in respect of dimensional accuracy and deflection behavior (FIG. 2). In contrast, components made using the conventional ceramic were characterized by considerable distortion both in the stacking direction of the component (FIG. 2a) and transverse to the stacking direction (FIG. 2b).

### REFERENCE SYMBOLS

KS Ceramic layer
EL Internal copper electrode
AT Subregions adjoining electrode layer
ET Subregions further away from electrode layer

1. A hard lead zirconate titanate (PZT) ceramic of the general structure ABO3, characterized in that the PZT ceramic has doping with Mn on the B sites and additionally doping with Cu on the A sites and/or on the B sites.

2. The PZT ceramic as claimed in the preceding claim, wherein the A sites have at least one further doping with Na, K, Ag, Nd, La, Ba, Sr, Ca or Bi, preferably Na and/or K.

3. The PZT ceramic as claimed in either of the preceding claims, wherein the B sites have at least one further doping with Fe, Nb, Zn, Ge, Sn, Al, Ga or Sb, preferably Nb.

4. The PZT ceramic as claimed in any of the preceding claims, wherein the doping on the A sites and/or B sites comprises up to 1.0 atom % of Cu, preferably from 0.05 to 0.1 atom % of Cu.

5. The PZT ceramic as claimed in any of the preceding claims, wherein the doping on the B sites comprises up to 5.0 atom % of Mn, preferably from 2.0 to 3.0 atom % of Mn.

6. The PZT ceramic as claimed in any of the preceding claims, wherein the ceramic has a general formula (Pb1-(a·2/m)Mma·2/m)1-y(Zr1-x-(b·4/n)TixNnb·4/n)yO3, where Mm represents one or more dopings having the respective valence m, Nn represents one or more dopings having the respective valence n and: 0≤a≤0.1; 0<b≤0.2; 0.2≤x≤0.8 and 0.4≤y≤0.6.

7. A process for producing a ceramic material comprising a hard lead zirconate titanate (PZT) ceramic as claimed in any of the preceding claims, comprising the steps:
A) Provision of starting materials Pb, Zr and Ti and doping elements Mn and Cu and optionally additional doping elements,
B) Mixing and milling of the starting materials and doping elements to produce a starting mixture,
C) Sintering of the starting mixture to the hard PZT ceramic in order to obtain the ceramic material.

8. The process as claimed in the preceding claim, wherein at least one of the doping elements, in particular Cu or, if present, Ag is present in a superstoichiometric proportion relative to the proportion of the doping element in the hard PZT ceramic in the starting mixture.

9. The process as claimed in either claim 7 or 8, wherein step C) is carried out in a sintering atmosphere in which at least one of the doping elements can change its valence.

10. The process as claimed in any of claims 7 to 9, wherein at least part of at least one of the doping elements is reduced to the metal in step C).

11. A ceramic material obtainable by the process as claimed in claim 10, wherein the ceramic material comprises the hard PZT ceramic and metallic precipitates, for example metallic particles, dispersed in the PZT ceramic.

12. The ceramic material as claimed in the preceding claim, wherein the metallic particles comprise at least one of the doping elements in elemental form, in particular elemental copper or elemental silver.

13. A ceramic composition comprising a ceramic component and a metallic component, wherein the ceramic component comprises a hard lead zirconate titanate (PZT) ceramic as claimed in any of claims 1 to 6 and the metallic component comprises a doping element, which is also present in the hard lead zirconate titanate (PZT) ceramic, in a form which has been reduced to the metal.

14. An electroceramic component, in particular a transducer, having a monolithic multilayer structure and comprising a stack of superposed ceramic layers and at least two electrode layers located inbetween, wherein the electrode layers contain elemental copper and the ceramic layers comprise a hard PZT ceramic as claimed in any of claims 1 to 6 or a ceramic material as claimed in claim 11 or a ceramic composition as claimed in claim 13.

15. The electroceramic component as claimed in the preceding claim, wherein a ceramic layer of the stack has subregions adjoining the electrode layers and subregions which are further away and are at a distance of more than 1.5 mm, in particular more than 2 mm or more than 4 mm, away from the electrode layers adjoining the ceramic layer.

16. The electroceramic component as claimed in the preceding claim, wherein the subregions adjoining the electrode layers and the subregions which are further away have Cu contents which differ by not more than 10%.

17. The piezoelectric component as claimed in any of claims 14 to 16, wherein the ceramic layers have a main surface which has a length of from 50 to 150 mm, preferably from 70 to 100 mm, and/or a width of from 4 to 25 mm, preferably from 6 to 18 mm.

18. The piezoelectric component as claimed in the preceding claim, wherein not more than 75%, in particular not more than 60% or not more than 50%, of the main surface of a ceramic layer is covered with an electrode layer.
